(19) United States
(12) Patent Application Publication
(10) Pub. No.: US 2026/0144040 A1
(43) Pub. Date: May 21, 2026

(54) SEMICONDUCTOR DEVICE STRUCTURE WITH LOW-K DIELECTRIC LAYER AND METHOD FOR FORMING THE SAME

(71) Applicant: Taiwan Semiconductor Manufacturing Company, Ltd., Hsinchu (TW)

(72) Inventors: Yang-Cheng SHIH, Hsinchu County (TW); Kuo-Chiang TSAI, Hsinchu City (TW)

(21) Appl. No.: 18/952,245

(22) Filed: Nov. 19, 2024

(51) Int. Cl. H01L 23/522; H01L 21/768; H01L 23/532; H01L 29/06; H01L 29/423; H01L 29/775; H01L 29/78; H01L 29/786

(52) U.S. Cl. CPC H10W 20/42; H10W 20/056; H10W 20/071; H10W 20/47; H10D 30/43; H10D 30/62; H10D 30/6735; H10D 30/6757; H10D 62/121

(57) ABSTRACT

A method for forming a semiconductor device structure is provided. The method includes providing a substrate, a first source/drain structure, a second source/drain structure, a gate stack, a first dielectric layer, and a contact structure over the substrate. The method includes forming an etch stop layer over the gate stack, the first dielectric layer, and the contact structure. The method includes forming a first low-k dielectric layer over the etch stop layer. The method includes forming a second dielectric layer over the first low-k dielectric layer, wherein a first dielectric constant of the first low-k dielectric layer is lower than a second dielectric constant of the second dielectric layer. The method includes forming a conductive via structure passing through the second dielectric layer, the first low-k dielectric layer, and the etch stop layer.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs.

In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, since feature sizes continue to decrease, RC time delay becomes more critical. Therefore, it is a challenge to reduce RC time delay at smaller and smaller sizes.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A-1E are cross-sectional views of various stages of a process for forming a semiconductor device structure, in accordance with some embodiments.

FIG. 1A-1 is a perspective view of the semiconductor device structure of FIG. 1A, in accordance with some embodiments.

FIGS. 2A-2C are cross-sectional views of various stages of a process for forming a semiconductor device structure, in accordance with some embodiments.

FIGS. 3A-3D are cross-sectional views of various stages of a process for forming a semiconductor device structure, in accordance with some embodiments.

FIGS. 4A-4D are cross-sectional views of various stages of a process for forming a semiconductor device structure, in accordance with some embodiments.

FIGS. 5A-5C are cross-sectional views of various stages of a process for forming a semiconductor device structure, in accordance with some embodiments.

FIG. 5A-1 is a top view of the semiconductor device structure of FIG. 5A, in accordance with some embodiments.

FIG. 5A-2 is a perspective view of the semiconductor device structure of FIG. 5A, in accordance with some embodiments.

FIG. 6 is a cross-sectional view of a semiconductor device structure, in accordance with some embodiments.

FIGS. 7A-7B are cross-sectional views of various stages of a process for forming a semiconductor device structure, in accordance with some embodiments.

FIGS. 8A-8B are cross-sectional views of various stages of a process for forming a semiconductor device structure, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. The term “substantially” may be varied in different technologies and be in the deviation range understood by the skilled in the art. For example, the term “substantially” may also relate to 90% of what is specified or higher, such as 95% of what is specified or higher, especially 99% of what is specified or higher, including 100% of what is specified, though the present invention is not limited thereto. Furthermore, terms such as “substantially parallel” or “substantially perpendicular” may be interpreted as not to exclude insignificant deviation from the specified arrangement and may include for example deviations of up to 10°. The word “substantially” does not exclude “completely” e.g. a composition which is “substantially free” from Y may be completely free from Y.

The term “about” may be varied in different technologies and be in the deviation range understood by the skilled in the art. The term “about” in conjunction with a specific distance or size is to be interpreted so as not to exclude insignificant deviation from the specified distance or size. For example, the term “about” may include deviations of up to 10% of what is specified, though the present invention is not limited thereto. The term “about” in relation to a numerical value x may mean x ±5 or 10% of what is specified, though the present invention is not limited thereto.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

Embodiments of the disclosure form a semiconductor device structure with FinFETs. The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. Source/drain structure(s) may refer to a source or a drain, individually or collectively dependent upon the context.

The nanostructure transistor (e.g. nanosheet transistor, nanowire transistor, multi-bridge channel, nano-ribbon FET, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

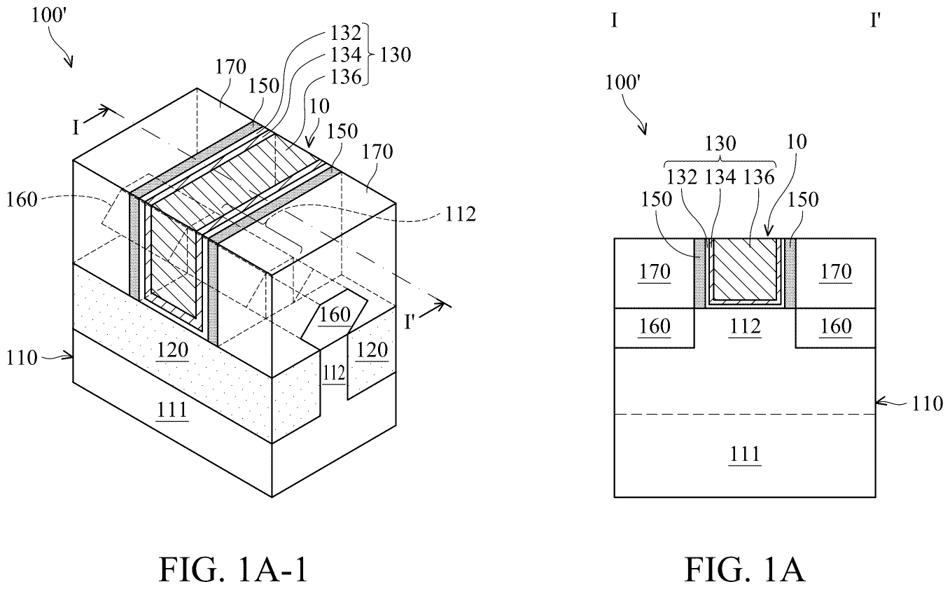

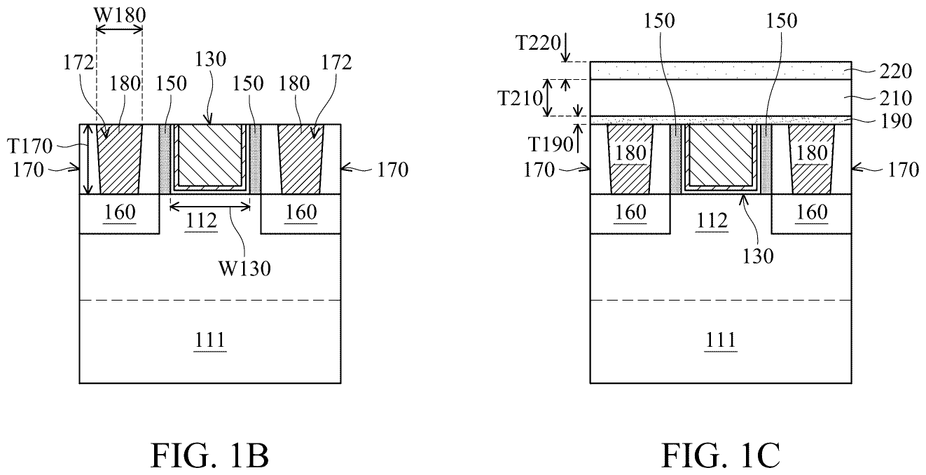

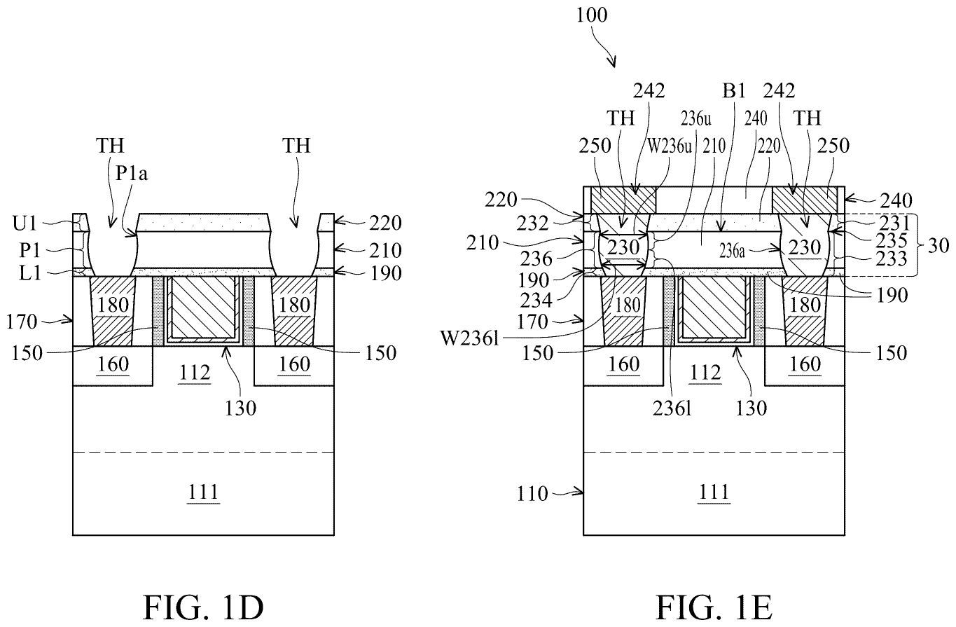

FIGS. 1A-1E are cross-sectional views of various stages of a process for forming a semiconductor device structure, in accordance with some embodiments. FIG. 1A-1 is a perspective view of the semiconductor device structure of FIG. 1A, in accordance with some embodiments. FIG. 1A is a cross-sectional view illustrating the semiconductor device structure along a sectional line I-I′ in FIG. 1A-1, in accordance with some embodiments.

As shown in FIGS. 1A and 1A-1, a semiconductor device structure 100′ is provided, in accordance with some embodiments. The semiconductor device structure 100′ includes a substrate 110, an isolation layer 120, a gate stack 130, a spacer layer 150, source/drain structures 160, and a dielectric layer 170, in accordance with some embodiments.

The substrate 110 has a base 111 and a fin structure 112 over the base 111, in accordance with some embodiments. The substrate 110 includes, for example, a semiconductor substrate. The substrate 110 includes, for example, a semiconductor wafer (such as a silicon wafer) or a portion of a semiconductor wafer.

In some embodiments, the substrate 110 is made of an elementary semiconductor material including silicon or germanium in a single crystal structure, a polycrystal structure, or an amorphous structure. In some other embodiments, the substrate 110 is made of a compound semiconductor, such as silicon carbide, gallium arsenide, gallium phosphide, indium phosphide, indium arsenide, an alloy semiconductor, such as SiGe or GaAsP, or a combination thereof. The substrate 110 may also include multi-layer semiconductors, semiconductor on insulator (SOI) (such as silicon on insulator or germanium on insulator), or a combination thereof.

In some embodiments, the substrate 110 is a device wafer that includes various device elements. In some embodiments, the various device elements are formed in and/or over the substrate 110. The device elements are not shown in figures for the purpose of simplicity and clarity. Examples of the various device elements include active devices, passive devices, other suitable elements, or a combination thereof. The active devices may include transistors or diodes (not shown) formed at a surface of the substrate 110. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc. Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate 110. The isolation features are used to surround active regions and electrically isolate various device elements formed in and/or over the substrate 110 in the active regions. In some embodiments, the isolation features include shallow trench isolation (STI) features, local oxidation of silicon (LOCOS) features, other suitable isolation features, or a combination thereof.

As shown in FIG. 1A-1, the isolation layer 120 is formed over the base 111, in accordance with some embodiments. The isolation layer 120 surrounds a lower portion of the fin structure 112, in accordance with some embodiments. The fin structure 112 is partially in the isolation layer 120, in accordance with some embodiments. The isolation layer 120 includes oxide (such as silicon oxide), in accordance with some embodiments. The isolation layer 120 is formed by a chemical vapor deposition (CVD) process and an etching back process, in accordance with some embodiments.

As shown in FIGS. 1A and 1A-1, a gate stack 130 is formed over and across the fin structure 112, in accordance with some embodiments. The gate stack 130 has a gate dielectric layer 132, a work function metal layer 134, and a gate electrode 136, in accordance with some embodiments.

The gate dielectric layer 132 conformally covers the spacer layer 150, the isolation layer 120, and the fin structure 112, in accordance with some embodiments. The gate dielectric layer 132 is positioned between the work function metal layer 134 and the fin structure 112, in accordance with some embodiments. The gate dielectric layer 132 is also positioned between the work function metal layer 134 and the isolation layer 120, in accordance with some embodiments.

In some embodiments, a dielectric constant of the gate dielectric layer 132 is greater than a dielectric constant of silicon dioxide. The gate dielectric layer 132 is also referred to as a high dielectric-constant (high-k) layer, in accordance with some embodiments.

The gate dielectric layer 132 is made of a high-k dielectric material, such as hafnium dioxide, zirconium oxide, aluminum oxide, hafnium dioxide-alumina alloy, hafnium silicon oxide, hafnium silicon oxynitride, hafnium tantalum oxide, hafnium titanium oxide, hafnium zirconium oxide, another suitable high-K material, or a combination thereof.

The formation of the gate dielectric layer 132 includes conformally depositing the gate dielectric layer 132 over the spacer layer 150, the isolation layer 120, and the fin structure 112, in accordance with some embodiments. The deposition process includes a chemical vapor deposition process, an atomic layer deposition (ALD) process, or a physical vapor deposition process, in accordance with some embodiments.

In some other embodiments (not shown), an interfacial layer is formed over the fin structure 112 before the formation of the gate dielectric layer 132 to improve the adhesion between the gate dielectric layer 132 and the fin structure 112. The interfacial layer is made of an oxide-containing material such as silicon oxide, in accordance with some embodiments.

As shown in FIGS. 1A and 1A-1, the work function metal layer 134 is formed over the gate dielectric layer 132, in accordance with some embodiments. The work function metal layer 134 provides a desired work function for a transistor to enhance device performance including improved threshold voltage.

In the embodiments of forming a PMOS transistor, the work function metal layer 134 is used to provide a work function value suitable for the device, such as equal to or greater than about 4.8 eV. The work function metal layer 134 may be made of metal, metal carbide, metal nitride, other suitable materials, or a combination thereof. For example, the work function metal layer 134 is made of titanium, titanium nitride, other suitable materials, or a combination thereof.

In the embodiments of forming an NMOS transistor, the work function metal layer 134 is used to provide a work function value suitable for the device, such as equal to or less than about 4.5 eV. The work function metal layer 134 may be made of metal, metal carbide, metal nitride, or a combination thereof. For example, the work function metal layer 134 is made of tantalum, tantalum nitride, or a combination thereof.

The work function metal layer 134 is formed using a deposition process, in accordance with some embodiments. The deposition process includes an atomic layer deposition (ALD), a chemical vapor deposition (CVD) process, another suitable method, or a combination thereof.

As shown in FIGS. 1A and 1A-1, the gate electrode 136 is formed over the work function metal layer 134, in accordance with some embodiments. The gate electrode 136 is made of a suitable conductive material, such as metal (e.g., aluminum, tungsten, gold, platinum, or cobalt), an alloy thereof, or a combination thereof, in accordance with some embodiments.

The gate electrode 136 is formed using a deposition process and a planarization process, in accordance with some embodiments. The deposition process includes a physical vapor deposition (PVD) process, a chemical vapor deposition (CVD) process, or an atomic layer deposition (ALD) process, in accordance with some embodiments. The planarization process includes a chemical mechanical polishing (CMP) process, in accordance with some embodiments.

As shown in FIGS. 1A and 1A-1, the spacer layer 150 is formed over sidewalls of the gate stack 130, in accordance with some embodiments. The spacer layer 150 surrounds the gate stack 130, in accordance with some embodiments. The spacer layer 150 is positioned over the fin structure 112 and the isolation layer 120, in accordance with some embodiments.

The spacer layer 150 includes insulating materials, such as silicon oxide, silicon nitride, silicon oxynitride, or silicon carbide, in accordance with some embodiments. The formation of the spacer layer 150 includes a deposition process and an anisotropic etching process, in accordance with some embodiments.

As shown in FIGS. 1A and 1A-1, the source/drain structures 160 are formed over the fin structure 112, in accordance with some embodiments. The source/drain structures 160 are in direct contact with the fin structure 112, in accordance with some embodiments.

The source/drain structures 160 are positioned on two opposite sides of the gate stack 130, in accordance with some embodiments. In some embodiments, the source/drain structures 160 include a source structure and a drain structure.

In some embodiments, the source/drain structures 160 are made of a semiconductor material (e.g., silicon) with N-type dopants, such as the Group VA element, in accordance with some embodiments. The Group VA element includes phosphor (P), antimony (Sb), or another suitable Group VA material.

In some other embodiments, the source/drain structures 160 are made of a semiconductor material (e.g., silicon germanium) with P-type dopants, such as the Group IIIA element, in accordance with some embodiments. The Group IIIA element includes boron or another suitable material. The source/drain structures 160 are formed using an epitaxial process, in accordance with some embodiments.

As shown in FIGS. 1A and 1A-1, the dielectric layer 170 is formed over the isolation layer 120 and the source/drain structures 160, in accordance with some embodiments. The dielectric layer 170 surrounds the gate stack 130, in accordance with some embodiments.

The dielectric layer 170 includes an oxide-containing material such as silicon oxide, in accordance with some embodiments. The dielectric layer 170 is formed by a deposition process and a planarization process, in accordance with some embodiments. The deposition process includes a chemical vapor deposition (CVD) process, in accordance with some embodiments. The planarization process includes a chemical mechanical polishing (CMP) process, in accordance with some embodiments.

The gate stack 130 and the source/drain structures 160 together form a transistor 10, in accordance with some embodiments. The transistor 10 includes a fin field-effect transistor (FinFET), in accordance with some embodiments.

As shown in FIG. 1B, portions of the dielectric layer 170 are removed to form through holes 172 in the dielectric layer 170, in accordance with some embodiments. The through holes 172 expose the source/drain structures 160, in accordance with some embodiments. The removal process includes a photolithography process and an etching process, in accordance with some embodiments.

As shown in FIG. 1B, contact structures 180 are formed in the through holes 172, in accordance with some embodiments. The contact structures 180 pass through the dielectric layer 170, in accordance with some embodiments. The contact structures 180 are connected to the source/drain structures 160 respectively, in accordance with some embodiments.

The thickness T170 of the dielectric layer 170 ranges from about 1 nm to about 50 nm, in accordance with some embodiments. The width W180 of the contact structure 180 ranges from about 1 nm to about 50 nm, in accordance with some embodiments. The width W130 of the gate stack 130 ranges from about 1 nm to about 50 nm, in accordance with some embodiments.

The contact structures 180 are made of a metal material (e.g., tungsten, aluminum, gold, silver, or a combination thereof), an alloy thereof, or another suitable conductive material. The contact structures 180 are formed using a deposition process and a planarization process, in accordance with some embodiments.

The deposition process includes a physical vapor deposition (PVD) process, in accordance with some embodiments. The planarization process includes a chemical mechanical polishing (CMP) process, in accordance with some embodiments.

As shown in FIG. 1C, an etch stop layer 190 is formed over the gate stack 130, the spacer layer 150, the dielectric layer 170, and the contact structures 180, in accordance with some embodiments. The thickness T190 of the etch stop layer 190 ranges from about 1 nm to about 30 nm, in accordance with some embodiments.

The etch stop layer 190 is made of an insulating material, such as a nitrogen-containing material (e.g., silicon nitride), in accordance with some embodiments. The dielectric constant of the etch stop layer 190 ranges from about 6 to about 7, in accordance with some embodiments.

The etch stop layer 190 is formed using a deposition process, such as a chemical vapor deposition (CVD) process, an atomic layer deposition (ALD) process, or a physical vapor deposition (PVD) process, in accordance with some embodiments.

As shown in FIG. 1C, a low-k dielectric layer 210 is formed over the etch stop layer 190, in accordance with some embodiments. The dielectric constant of the low-k dielectric layer 210 is lower than the dielectric constant of the etch stop layer 190, in accordance with some embodiments.

Since the dielectric material with a lower dielectric constant has a higher porosity, the porosity of the low-k dielectric layer 210 is greater than the porosity of the etch stop layer 190, in accordance with some embodiments. The density of the low-k dielectric layer 210 is lower than the density of the etch stop layer 190, in accordance with some embodiments.

The low-k dielectric layer 210 has a dielectric constant which is lower than about 3.5, in accordance with some embodiments. The dielectric constant of the low-k dielectric layer 210 ranges from about 2 to about 3.5, in accordance with some embodiments. The thickness T210 of the low-k dielectric layer 210 ranges from about 1 nm to about 80 nm, in accordance with some embodiments.

The low-k dielectric layer 210 is made of a low-k dielectric material, such as a nitride material (e.g., silicon nitride), an oxide material (e.g., silicon oxide), a carbide material (e.g., SiCN, SiCON, or SiCOH), black diamond, or a porous material, in accordance with some embodiments.

The low-k dielectric layer 210 is formed using a deposition process, such as a chemical vapor deposition (CVD) process, an atomic layer deposition (ALD) process, or a physical vapor deposition (PVD) process, in accordance with some embodiments.

As shown in FIG. 1C, a dielectric layer 220 is formed over the low-k dielectric layer 210, in accordance with some embodiments. The dielectric constant of the low-k dielectric layer 210 is lower than the dielectric constant of the dielectric layer 220, in accordance with some embodiments. The dielectric constant of the dielectric layer 220 ranges from about 3.8 to about 4.2, in accordance with some embodiments.

The density of the low-k dielectric layer 210 is lower than the density of the dielectric layer 220, in accordance with some embodiments. The porosity of the low-k dielectric layer 210 is greater than the porosity of the dielectric layer 220, in accordance with some embodiments.

The dielectric layer 220 is thicker than the etch stop layer 190, in accordance with some embodiments. The thickness T220 of the dielectric layer 220 ranges from about 1 nm to about 80 nm, in accordance with some embodiments.

The dielectric layer 220 includes an oxide-containing material (e.g., silicon oxide or tetraethyl orthosilicate oxide), an oxynitride-containing material (e.g., silicon oxynitride), a glass material (e.g., borosilicate glass, phosphoric silicate glass, boron phospho-silicate glass, or fluorinated silicate glass), or a combination thereof, in accordance with some embodiments.

The dielectric layer 220 is formed using a chemical vapor deposition (CVD) process, such as a low-pressure CVD process, a plasma-enhanced CVD process, or a high-density plasma CVD process, an atomic layer deposition process, a spin-on process, a physical vapor deposition process, or another suitable process, in accordance with some embodiments.

As shown in FIG. 1D, portions of the etch stop layer 190, the low-k dielectric layer 210, and the dielectric layer 220 are removed to form through holes TH in the etch stop layer 190, the low-k dielectric layer 210, and the dielectric layer 220, in accordance with some embodiments. The through holes TH expose the contact structures 180 respectively, in accordance with some embodiments.

Since the porosity of the low-k dielectric layer 210 is higher than that of the dielectric layer 220 and the etch stop layer 190, the etching rate of the low-k dielectric layer 210 is greater than that of the dielectric layer 220 and the etch stop layer 190 in the removal process, in accordance with some embodiments.

As a result, the through hole TH has an upper portion U1, a lower portion L1, and a wide portion P1 between the upper portion U1 and the lower portion L1, and the wide portion P1 is wider than both the upper portion U1 and the lower portion L1, in accordance with some embodiments.

The upper portion U1 passes through the dielectric layer 220, in accordance with some embodiments. The lower portion L1 passes through the etch stop layer 190, in accordance with some embodiments. The wide portion P1 passes through the low-k dielectric layer 210, in accordance with some embodiments.

The wide portion P1 has a concaved curved inner wall P1a, in accordance with some embodiments. The removal process includes a photolithography process and an etching process, in accordance with some embodiments.

As shown in FIG. 1E, conductive via structures 230 are formed in the through holes TH respectively, in accordance with some embodiments. The conductive via structures 230 pass through the dielectric layer 220, the low-k dielectric layer 210, and the etch stop layer 190, in accordance with some embodiments. The conductive via structures 230 are connected to the contact structures 180 respectively, in accordance with some embodiments.

Each conductive via structure 230 has end portions 232 and 234 and a middle portion 236 connected between the end portion 232 and the end portion 234, in accordance with some embodiments. The end portion 232 passes through the dielectric layer 220, in accordance with some embodiments.

The end portion 234 passes through the etch stop layer 190, in accordance with some embodiments. The middle portion 236 passes through the low-k dielectric layer 210, in accordance with some embodiments. The middle portion 236 has a convex curved sidewall 236a, in accordance with some embodiments.

The middle portion 236 is wider than the end portion 232, in accordance with some embodiments. The middle portion 236 is wider than the end portion 234, in accordance with some embodiments.

The middle portion 236 has an upper part 236u and a lower part 236l, in accordance with some embodiments. The width W236u of the upper part 236u decreases toward the end portion 232, in accordance with some embodiments. The width W236l of the lower part 236l decreases toward the end portion 234, in accordance with some embodiments.

Each conductive via structure 230 has an upper portion 231, a lower portion 233, and a neck portion 235 connected between the upper portion 231 and the lower portion 233, in accordance with some embodiments. The neck portion 235 is narrower than the upper portion 231, in accordance with some embodiments.

The neck portion 235 is narrower than the lower portion 233, in accordance with some embodiments. The neck portion 235 is substantially level with a boundary B1 between the low-k dielectric layer 210 and the dielectric layer 220, in accordance with some embodiments.

As shown in FIG. 1E, a dielectric layer 240 is formed over the dielectric layer 220 and the conductive via structures 230, in accordance with some embodiments. The dielectric layer 240 includes an oxide-containing material (e.g., silicon oxide or tetraethyl orthosilicate oxide), an oxynitride-containing material (e.g., silicon oxynitride), a glass material (e.g., borosilicate glass, phosphoric silicate glass, boron phospho-silicate glass, or fluorinated silicate glass), or a combination thereof, in accordance with some embodiments.

The dielectric layer 240 is formed using a chemical vapor deposition (CVD) process, such as a low-pressure CVD process, a plasma-enhanced CVD process, or a high-density plasma CVD process, an atomic layer deposition process, a spin-on process, a physical vapor deposition process, or another suitable process, in accordance with some embodiments.

As shown in FIG. 1E, portions of the dielectric layer 240 are removed to form trenches 242 in the dielectric layer 240, in accordance with some embodiments. The trenches 242 expose the conductive via structures 230, in accordance with some embodiments. The removal process includes a photolithography process and an etching process, in accordance with some embodiments.

As shown in FIG. 1E, a wiring layer 250 is formed in the trenches 242 of the dielectric layer 240, in accordance with some embodiments. The wiring layer 250 is connected to the conductive via structures 230, in accordance with some embodiments. The wiring layer 250 is made of a metal material (e.g., tungsten, aluminum, gold, silver, or a combination thereof), an alloy thereof, or another suitable conductive material.

In this step, a semiconductor device structure 100 is substantially formed, in accordance with some embodiments.

The etch stop layer 190, the low-k dielectric layer 210 and the dielectric layer 220 together form a dielectric structure 30, in accordance with some embodiments. The dielectric structure 30 is between the wiring layer 250 and the gate stack 130 and between the wiring layer 250 and the contact structures 180, in accordance with some embodiments.

The application forms the low-k dielectric layer 210 with a low dielectric constant between the etch stop layer 190 and the dielectric layer 220 to reduce the dielectric constant of the dielectric structure 30, in accordance with some embodiments. Therefore, the capacitor between the wiring layer 250 and the gate stack 130 and between the wiring layer 250 and the contact structures 180 is reduced, which reduces RC time delay between the wiring layer 250 and the gate stack 130 and between the wiring layer 250 and the contact structures 180, in accordance with some embodiments. As a result, the performance of the semiconductor device structure 100 is improved, in accordance with some embodiments.

Since the dielectric structure 30 has the etch stop layer 190 and the dielectric layer 220 with greater etch resistance (than the low-k dielectric layer 210), the yield of the etching process for forming the through holes TH is maintained, in accordance with some embodiments. The etch stop layer 190 protects the gate stack 130 from oxidation caused by oxygen atoms in the low-k dielectric layer 210, in accordance with some embodiments.

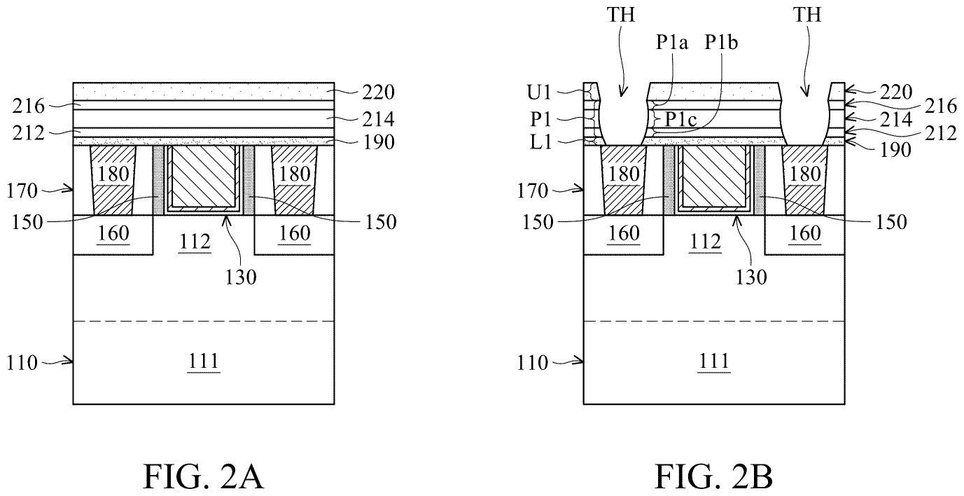

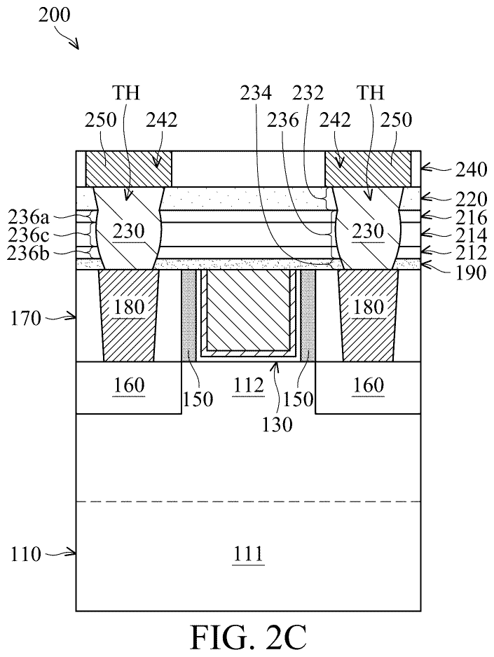

FIGS. 2A-2C are cross-sectional views of various stages of a process for forming a semiconductor device structure, in accordance with some embodiments. As shown in FIG. 2A, after the step of FIG. 1B is performed, the etch stop layer 190 is formed over the gate stack 130, the spacer layer 150, the dielectric layer 170, and the contact structures 180, in accordance with some embodiments.

Thereafter, as shown in FIG. 2A, a low-k dielectric layer 212 is formed over the etch stop layer 190, in accordance with some embodiments. The dielectric constant of the low-k dielectric layer 212 is lower than the dielectric constant of the etch stop layer 190, in accordance with some embodiments.

The low-k dielectric layer 212 has a dielectric constant which is lower than about 3.5, in accordance with some embodiments. The dielectric constant of the low-k dielectric layer 212 ranges from about 2 to about 3.5, in accordance with some embodiments.

The low-k dielectric layer 212 is made of a low-k dielectric material, such as a nitride material (e.g., silicon nitride), an oxide material (e.g., silicon oxide), a carbide material (e.g., SiCN, SiCON, or SiCOH), black diamond, or a porous material, in accordance with some embodiments.

The low-k dielectric layer 212 is formed using a deposition process, such as a chemical vapor deposition (CVD) process, an atomic layer deposition (ALD) process, or a physical vapor deposition (PVD) process, in accordance with some embodiments.

Thereafter, as shown in FIG. 2A, a low-k dielectric layer 214 is formed over the low-k dielectric layer 212, in accordance with some embodiments. The dielectric constant of the low-k dielectric layer 214 is lower than the dielectric constant of the low-k dielectric layer 212, in accordance with some embodiments.

The low-k dielectric layer 214 has a dielectric constant which is lower than about 3.5, in accordance with some embodiments. The dielectric constant of the low-k dielectric layer 214 ranges from about 2 to about 3.5, in accordance with some embodiments.

The low-k dielectric layer 214 is made of a low-k dielectric material, such as a nitride material (e.g., silicon nitride), an oxide material (e.g., silicon oxide), a carbide material (e.g., SiCN, SiCON, or SiCOH), black diamond, or a porous material, in accordance with some embodiments.

The low-k dielectric layer 214 is formed using a deposition process, such as a chemical vapor deposition (CVD) process, an atomic layer deposition (ALD) process, or a physical vapor deposition (PVD) process, in accordance with some embodiments.

Thereafter, as shown in FIG. 2A, a low-k dielectric layer 216 is formed over the low-k dielectric layer 214, in accordance with some embodiments. The dielectric constant of the low-k dielectric layer 214 is lower than the dielectric constant of the low-k dielectric layer 216, in accordance with some embodiments.

The low-k dielectric layer 216 has a dielectric constant which is lower than about 3.5, in accordance with some embodiments. The dielectric constant of the low-k dielectric layer 216 ranges from about 2 to about 3.5, in accordance with some embodiments.

The low-k dielectric layer 216 is made of a low-k dielectric material, such as a nitride material (e.g., silicon nitride), an oxide material (e.g., silicon oxide), a carbide material (e.g., SiCN, SiCON, or SiCOH), black diamond, or a porous material, in accordance with some embodiments.

The low-k dielectric layer 216 is formed using a deposition process, such as a chemical vapor deposition (CVD) process, an atomic layer deposition (ALD) process, or a physical vapor deposition (PVD) process, in accordance with some embodiments.

Thereafter, as shown in FIG. 2A, the dielectric layer 220 is formed over the low-k dielectric layer 216, in accordance with some embodiments. The dielectric constant of the low-k dielectric layer 216 is lower than the dielectric constant of the dielectric layer 220, in accordance with some embodiments. The dielectric constant of the dielectric layer 220 ranges from about 3.8 to about 4.2, in accordance with some embodiments.

As shown in FIG. 2B, portions of the etch stop layer 190, the low-k dielectric layers 212, 214 and 216, and the dielectric layer 220 are removed to form through holes TH in the etch stop layer 190, the low-k dielectric layers 212, 214 and 216, and the dielectric layer 220, in accordance with some embodiments.

The through holes TH expose the contact structures 180 respectively, in accordance with some embodiments. Since the dielectric material with a lower dielectric constant may have a higher porosity, the porosity of the low-k dielectric layer 214 may be higher than that of the low-k dielectric layers 212 and 216, and the porosity of the low-k dielectric layers 212 and 216 may be higher than that of the dielectric layer 220 and the etch stop layer 190.

Therefore, in the removal process, the etching rate of the low-k dielectric layer 214 is greater than that of the low-k dielectric layers 212 and 216, and the etching rate of the low-k dielectric layers 212 and 216 is greater than that of the dielectric layer 220 and the etch stop layer 190, in accordance with some embodiments.

As a result, the through hole TH has an upper portion U1, a lower portion L1, and a wide portion P1 between the upper portion U1 and the lower portion L1, and the wide portion P1 is wider than both the upper portion U1 and the lower portion L1, in accordance with some embodiments.

The upper portion U1 passes through the dielectric layer 220, in accordance with some embodiments. The lower portion L1 passes through the etch stop layer 190, in accordance with some embodiments. The wide portion P1 passes through the low-k dielectric layers 212, 214, and 216, in accordance with some embodiments.

The wide portion P1 has an upper part P1a, a lower part P1b, and a middle part P1c between the upper part P1a and the lower part P1b, in accordance with some embodiments. The upper part P1a, the lower part P1b, and the middle part P1c pass through the low-k dielectric layers 216, 212, and 214 respectively, in accordance with some embodiments.

The middle part P1c is wider than the upper part P1a, in accordance with some embodiments. The middle part P1c is wider than the lower part P1b, in accordance with some embodiments. The removal process includes a photolithography process and an etching process, in accordance with some embodiments.

As shown in FIG. 2C, the step of FIG. 1E is performed to form the conductive via structures 230 in the through holes TH respectively, in accordance with some embodiments. The conductive via structures 230 pass through the dielectric layer 220, the low-k dielectric layers 212, 214, and 216, and the etch stop layer 190, in accordance with some embodiments. The conductive via structures 230 are connected to the contact structures 180 respectively, in accordance with some embodiments.

Each conductive via structure 230 has the end portions 232 and 234 and the middle portion 236 connected between the end portion 232 and the end portion 234, in accordance with some embodiments. The middle portion 236 is wider than the end portion 232, in accordance with some embodiments. The middle portion 236 is wider than the end portion 234, in accordance with some embodiments.

The middle portion 236 has an upper part 236a, a lower part 236b, and a middle part 236c between the upper part 236a and the lower part 236b, in accordance with some embodiments. The upper part 236a, the lower part 236b, and the middle part 236c pass through the low-k dielectric layers 216, 212, and 214 respectively, in accordance with some embodiments.

The middle part 236c is wider than the upper part 236a, in accordance with some embodiments. The middle part 236c is wider than the lower part 236b, in accordance with some embodiments.

As shown in FIG. 2C, the step of FIG. 1E is performed to form the dielectric layer 240 and the wiring layer 250, in accordance with some embodiments. In this step, a semiconductor device structure 200 is substantially formed, in accordance with some embodiments.

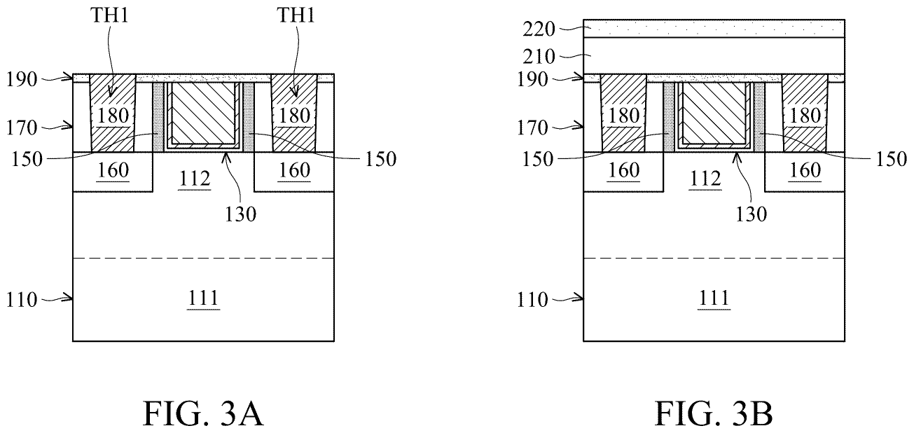

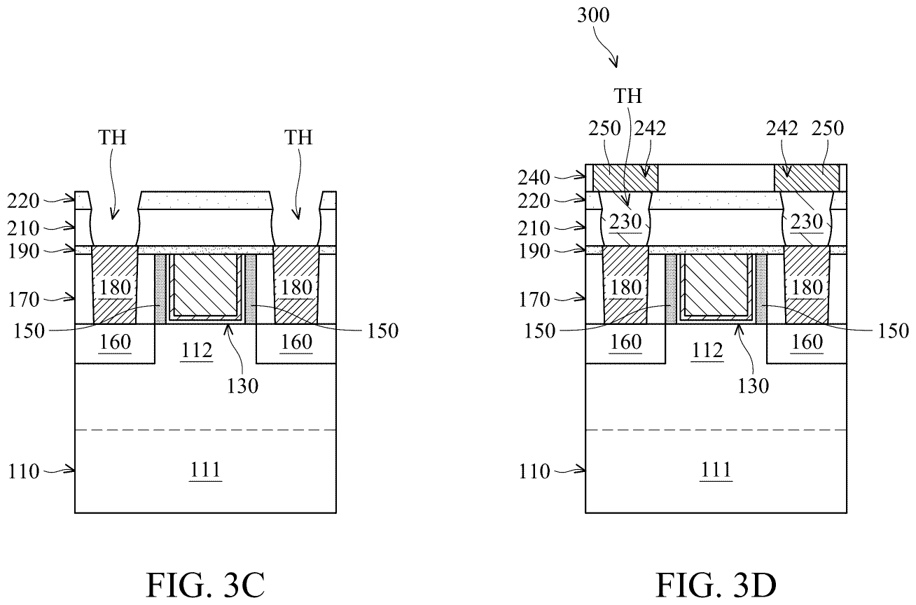

FIGS. 3A-3D are cross-sectional views of various stages of a process for forming a semiconductor device structure, in accordance with some embodiments. As shown in FIG. 3A, after the step of FIG. 1A, the etch stop layer 190 is formed over the gate stack 130, the spacer layer 150, and the dielectric layer 170, in accordance with some embodiments.

As shown in FIG. 3A, portions of the dielectric layer 170 and the etch stop layer 190 are removed to form through holes TH1 in the dielectric layer 170 and the etch stop layer 190, in accordance with some embodiments. The through holes TH1 expose the source/drain structures 160, in accordance with some embodiments. The removal process includes a photolithography process and an etching process, in accordance with some embodiments.

As shown in FIG. 3A, contact structures 180 are formed in the through holes TH1, in accordance with some embodiments. The contact structures 180 pass through the dielectric layer 170 and the etch stop layer 190, in accordance with some embodiments. The contact structures 180 are connected to the source/drain structures 160 respectively, in accordance with some embodiments.

As shown in FIG. 3B, the step of FIG. 1C is performed to form the low-k dielectric layer 210 and the dielectric layer 220, in accordance with some embodiments.

As shown in FIG. 3C, the step of FIG. 1D is performed to form the through holes TH in the low-k dielectric layer 210 and the dielectric layer 220, in accordance with some embodiments.

As shown in FIG. 3D, the step of FIG. 1E is performed to form the conductive via structures 230, the dielectric layer 240, and the wiring layer 250, in accordance with some embodiments. In this step, a semiconductor device structure 300 is substantially formed, in accordance with some embodiments.

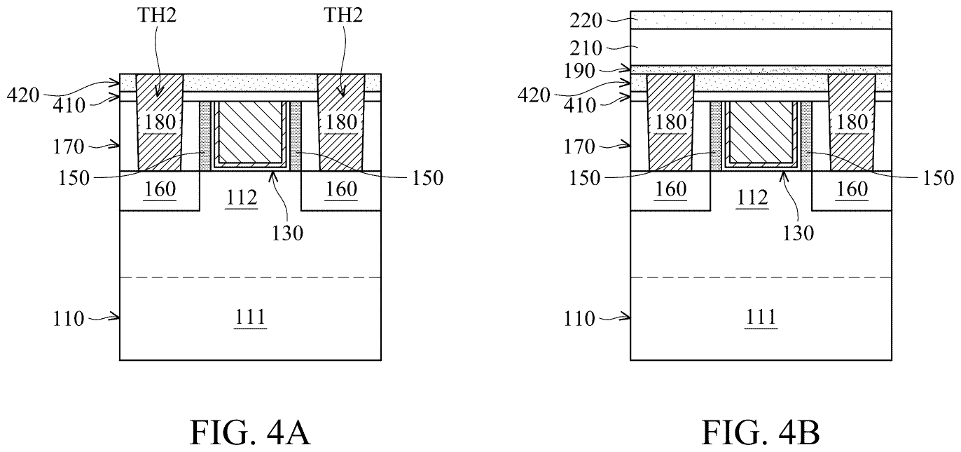

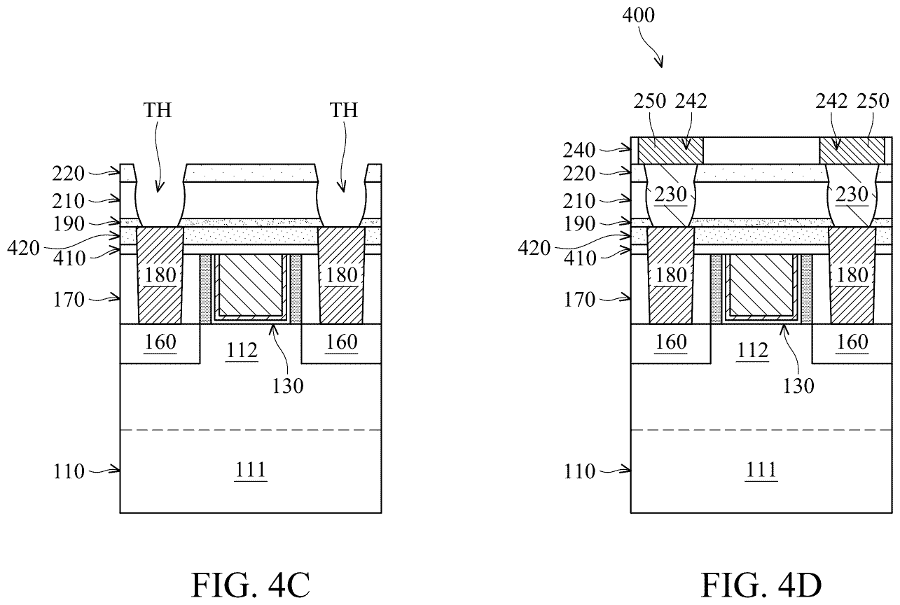

FIGS. 4A-4D are cross-sectional views of various stages of a process for forming a semiconductor device structure, in accordance with some embodiments. As shown in FIG. 4A, after the step of FIG. 1A is performed, an etch stop layer 410 is formed over the gate stack 130, the spacer layer 150, and the dielectric layer 170, in accordance with some embodiments.

The etch stop layer 410 is made of an insulating material, such as a nitrogen-containing material (e.g., silicon nitride), in accordance with some embodiments.

The etch stop layer 410 is formed using a deposition process, such as a chemical vapor deposition (CVD) process, an atomic layer deposition (ALD) process, or a physical vapor deposition (PVD) process, in accordance with some embodiments.

As shown in FIG. 4A, a dielectric layer 420 is formed over the etch stop layer 410, in accordance with some embodiments. The dielectric constant of the dielectric layer 420 ranges from about 3.8 to about 4.2, in accordance with some embodiments. The dielectric layer 420 is thicker than the etch stop layer 410, in accordance with some embodiments.

The dielectric layer 420 includes an oxide-containing material (e.g., silicon oxide or tetraethyl orthosilicate oxide), an oxynitride-containing material (e.g., silicon oxynitride), a glass material (e.g., borosilicate glass, phosphoric silicate glass, boron phospho-silicate glass, or fluorinated silicate glass), or a combination thereof, in accordance with some embodiments.

The dielectric layer 420 is formed using a chemical vapor deposition (CVD) process, such as a low-pressure CVD process, a plasma-enhanced CVD process, or a high-density plasma CVD process, an atomic layer deposition process, a spin-on process, a physical vapor deposition process, or another suitable process, in accordance with some embodiments.

Thereafter, as shown in FIG. 4A, portions of the dielectric layer 170, the etch stop layer 410, and the dielectric layer 420 are removed to form through holes TH2 in the dielectric layer 170, the etch stop layer 410, and the dielectric layer 420, in accordance with some embodiments.

The through holes TH2 expose the source/drain structures 160, in accordance with some embodiments. The removal process includes a photolithography process and an etching process, in accordance with some embodiments.

Thereafter, as shown in FIG. 4A, the step of FIG. 1B is performed to form the contact structures 180 in the through holes TH2, in accordance with some embodiments. The contact structures 180 are connected to the source/drain structures 160 respectively, in accordance with some embodiments.

As shown in FIG. 4B, the step of FIG. 1C is performed to form the etch stop layer 190, the low-k dielectric layer 210, and the dielectric layer 220 over the contact structures 180 and the dielectric layer 420, in accordance with some embodiments.

The dielectric constant of the low-k dielectric layer 210 is lower than the dielectric constant of the dielectric layer 420 and the etch stop layer 410, in accordance with some embodiments.

As shown in FIG. 4C, the step of FIG. 1D is performed to form the through holes TH in the etch stop layer 190, the low-k dielectric layer 210, and the dielectric layer 220, in accordance with some embodiments.

As shown in FIG. 4D, the step of FIG. 1E is performed to form the conductive via structures 230, the dielectric layer 240, and the wiring layer 250, in accordance with some embodiments. In this step, a semiconductor device structure 400 is substantially formed, in accordance with some embodiments.

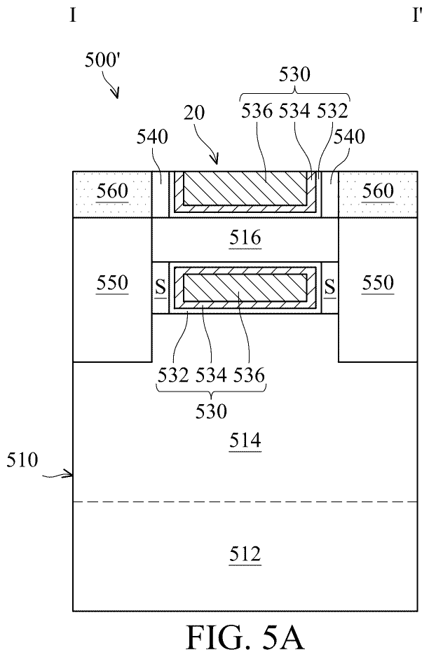

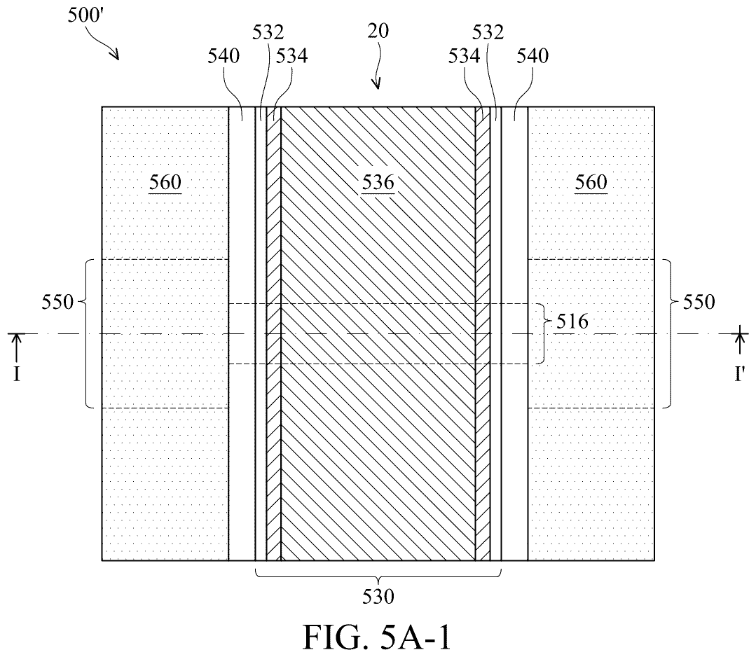

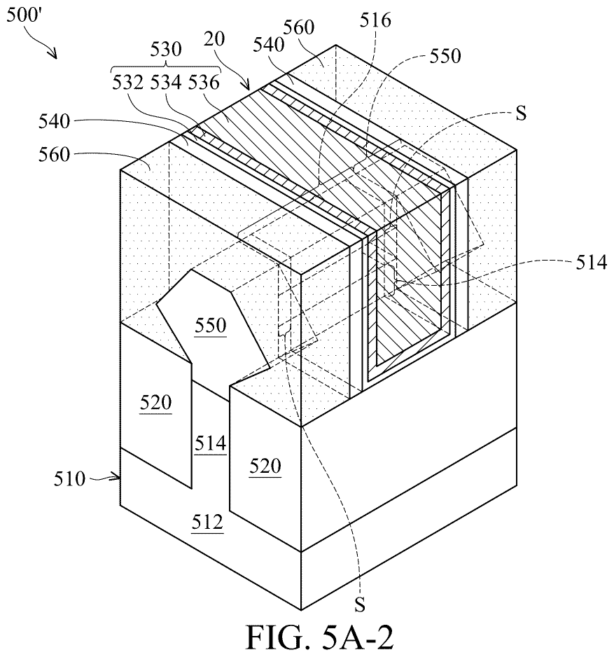

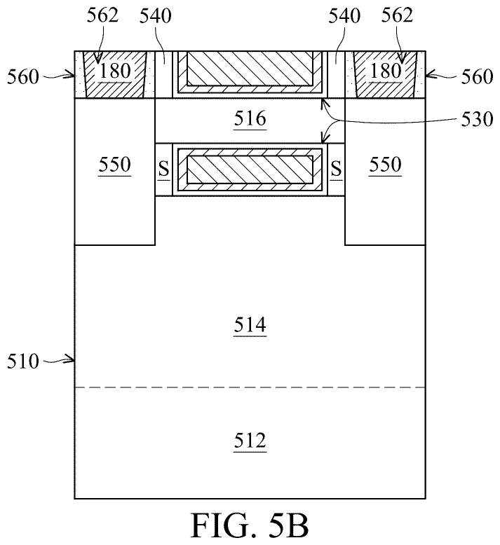

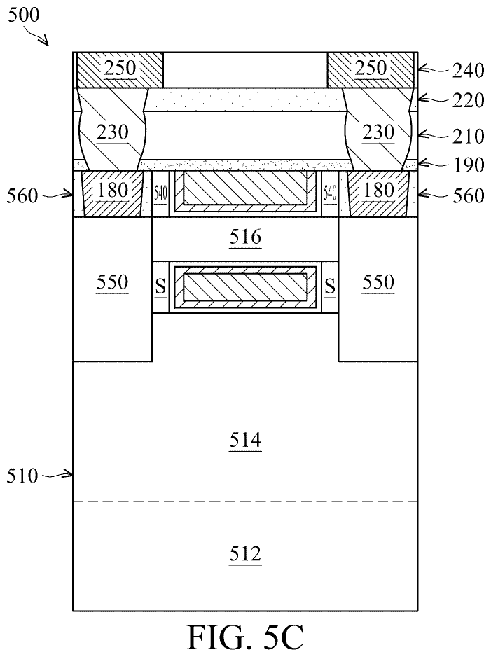

FIGS. 5A-5C are cross-sectional views of various stages of a process for forming a semiconductor device structure, in accordance with some embodiments. FIG. 5A-1 is a top view of the semiconductor device structure of FIG. 5A, in accordance with some embodiments.

FIG. 5A is a cross-sectional view illustrating the semiconductor device structure along a sectional line I-I′ in FIG. 5A-1, in accordance with some embodiments. FIG. 5A-2 is a perspective view of the semiconductor device structure of FIG. 5A, in accordance with some embodiments.

As shown in FIGS. 5A, 5A-1, and 5A-2, a semiconductor device structure 500′ is provided, in accordance with some embodiments. The semiconductor device structure 500′ includes a substrate 510, an isolation layer 520, a gate stack 530, a spacer layer 540, source/drain structures 550, a dielectric layer 560, and an inner spacer layer S, in accordance with some embodiments.

The substrate 510 has a base 512, a fin structure 514, and a nanostructure 516 over the base 512, in accordance with some embodiments. The nanostructure 516 is over the fin structure 514, in accordance with some embodiments. The nanostructure 516 includes a nanowire or a nanosheet, in accordance with some embodiments.

The substrate 510 includes, for example, a semiconductor substrate. The substrate 510 includes, for example, a semiconductor wafer (such as a silicon wafer) or a portion of a semiconductor wafer. In some embodiments, the substrate 510 is made of an elementary semiconductor material including silicon or germanium in a single crystal structure, a polycrystal structure, or an amorphous structure.

In some other embodiments, the substrate 510 is made of a compound semiconductor, such as silicon carbide, gallium arsenide, gallium phosphide, indium phosphide, indium arsenide, an alloy semiconductor, such as SiGe or GaAsP, or a combination thereof. The substrate 510 may also include multi-layer semiconductors, semiconductor on insulator (SOI) (such as silicon on insulator or germanium on insulator), or a combination thereof.

In some embodiments, the substrate 510 is a device wafer that includes various device elements. In some embodiments, the various device elements are formed in and/or over the substrate 510. The device elements are not shown in figures for the purpose of simplicity and clarity.

Examples of the various device elements include active devices, passive devices, other suitable elements, or a combination thereof. The active devices may include transistors or diodes (not shown) formed at a surface of the substrate 510. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc.

Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate 510. The isolation features are used to surround active regions and electrically isolate various device elements formed in and/or over the substrate 510 in the active regions. In some embodiments, the isolation features include shallow trench isolation (STI) features, local oxidation of silicon (LOCOS) features, other suitable isolation features, or a combination thereof.

As shown in FIG. 5A-2, the isolation layer 520 is formed over the base 512, in accordance with some embodiments. The isolation layer 520 surrounds a lower portion of the fin structure 514, in accordance with some embodiments. The fin structure 514 is partially in the isolation layer 520, in accordance with some embodiments.

The isolation layer 520 includes oxide (such as silicon oxide), in accordance with some embodiments. The isolation layer 520 is formed by a chemical vapor deposition (CVD) process and an etching back process, in accordance with some embodiments.

As shown in FIGS. 5A, 5A-1, and 5A-2, a gate stack 530 is formed over and across the fin structure 514 and the nanostructure 516, in accordance with some embodiments. The gate stack 530 surrounds the nanostructure 516, in accordance with some embodiments. The gate stack 530 has a gate dielectric layer 532, a work function metal layer 534, and a gate electrode 536, in accordance with some embodiments.

The gate dielectric layer 532 conformally covers the spacer layer 540, the isolation layer 520, the fin structure 514, and the nanostructure 516, in accordance with some embodiments. The gate dielectric layer 532 is positioned between the work function metal layer 534 and the fin structure 514, in accordance with some embodiments.

The gate dielectric layer 532 is positioned between the work function metal layer 534 and the nanostructure 516, in accordance with some embodiments. The gate dielectric layer 532 is also positioned between the work function metal layer 534 and the isolation layer 520, in accordance with some embodiments.

In some embodiments, a dielectric constant of the gate dielectric layer 532 is greater than a dielectric constant of silicon dioxide. The gate dielectric layer 532 is also referred to as a high dielectric-constant (high-k) layer, in accordance with some embodiments.

The gate dielectric layer 532 is made of a high-k dielectric material, such as hafnium dioxide, zirconium oxide, aluminum oxide, hafnium dioxide-alumina alloy, hafnium silicon oxide, hafnium silicon oxynitride, hafnium tantalum oxide, hafnium titanium oxide, hafnium zirconium oxide, another suitable high-K material, or a combination thereof.

The formation of the gate dielectric layer 532 includes conformally depositing the gate dielectric layer 532 over the spacer layer 540, the isolation layer 520, the fin structure 514, and the nanostructure 516, in accordance with some embodiments.

The deposition process includes a chemical vapor deposition process, an atomic layer deposition (ALD) process, or a physical vapor deposition process, in accordance with some embodiments.

In some other embodiments (not shown), an interfacial layer is formed over the fin structure 514 and the nanostructure 516 before the formation of the gate dielectric layer 532 to improve the adhesion between the gate dielectric layer 532, the fin structure 514, and the nanostructure 516. The interfacial layer is made of an oxide-containing material such as silicon oxide, in accordance with some embodiments.

As shown in FIGS. 5A, 5A-1, and 5A-2, the work function metal layer 534 is formed over the gate dielectric layer 532, in accordance with some embodiments. The work function metal layer 534 provides a desired work function for a transistor to enhance device performance including improved threshold voltage.

In the embodiments of forming a PMOS transistor, the work function metal layer 534 is used to provide a work function value suitable for the device, such as equal to or greater than about 4.8 eV. The work function metal layer 534 may be made of metal, metal carbide, metal nitride, other suitable materials, or a combination thereof. For example, the work function metal layer 534 is made of titanium, titanium nitride, other suitable materials, or a combination thereof.

In the embodiments of forming an NMOS transistor, the work function metal layer 534 is used to provide a work function value suitable for the device, such as equal to or less than about 4.5 eV. The work function metal layer 534 may be made of metal, metal carbide, metal nitride, or a combination thereof. For example, the work function metal layer 534 is made of tantalum, tantalum nitride, or a combination thereof.

The work function metal layer 534 is formed using a deposition process, in accordance with some embodiments. The deposition process includes an atomic layer deposition (ALD), a chemical vapor deposition (CVD) process, another suitable method, or a combination thereof.

As shown in FIGS. 5A, 5A-1, and 5A-2, the gate electrode 536 is formed over the work function metal layer 534, in accordance with some embodiments. The gate electrode 536 is made of a suitable conductive material, such as metal (e.g., aluminum, tungsten, gold, platinum, or cobalt), an alloy thereof, or a combination thereof, in accordance with some embodiments.

The gate electrode 536 is formed using a deposition process and a planarization process, in accordance with some embodiments. The deposition process includes a physical vapor deposition (PVD) process, a chemical vapor deposition (CVD) process, or an atomic layer deposition (ALD) process, in accordance with some embodiments. The planarization process includes a chemical mechanical polishing (CMP) process, in accordance with some embodiments.

As shown in FIGS. 5A, 5A-1, and 5A-2, the spacer layer 540 is formed over sidewalls of the gate stack 530, in accordance with some embodiments. The spacer layer 540 surrounds the gate stack 530, in accordance with some embodiments. The spacer layer 540 is positioned over the fin structure 514, the nanostructure 516, and the isolation layer 520, in accordance with some embodiments.

The spacer layer 540 includes insulating materials, such as silicon oxide, silicon nitride, silicon oxynitride, or silicon carbide, in accordance with some embodiments. The formation of the spacer layer 540 includes a deposition process and an anisotropic etching process, in accordance with some embodiments.

As shown in FIGS. 5A and 5A-2, the inner spacer layer S is formed over sidewalls of the gate stack 530, in accordance with some embodiments. The inner spacer layer S is between the gate stack 530 and the source/drain structures 550, in accordance with some embodiments.

The inner spacer layer S is between the fin structure 514 and the nanostructure 516, in accordance with some embodiments. The inner spacer layer S includes insulating materials, such as silicon oxide, silicon nitride, silicon oxynitride, or silicon carbide, in accordance with some embodiments. The formation of the inner spacer layer S includes a deposition process and an anisotropic etching process, in accordance with some embodiments.

As shown in FIGS. 5A, 5A-1, and 5A-2, the source/drain structures 550 are formed over the fin structure 514, in accordance with some embodiments. The source/drain structures 550 are in direct contact with the fin structure 514, in accordance with some embodiments. The source/drain structures 550 are in direct contact with the nanostructure 516, in accordance with some embodiments.

The source/drain structures 550 are positioned on two opposite sides of the gate stack 530, in accordance with some embodiments. The source/drain structures 550 are positioned on two opposite sides of the nanostructure 516, in accordance with some embodiments. In some embodiments, the source/drain structures 550 include a source structure and a drain structure.

In some embodiments, the source/drain structures 550 are made of a semiconductor material (e.g., silicon) with N-type dopants, such as the Group VA element, in accordance with some embodiments. The Group VA element includes phosphor (P), antimony (Sb), or another suitable Group VA material.

In some other embodiments, the source/drain structures 550 are made of a semiconductor material (e.g., silicon germanium) with P-type dopants, such as the Group IIIA element, in accordance with some embodiments. The Group IIIA element includes boron or another suitable material. The source/drain structures 550 are formed using an epitaxial process, in accordance with some embodiments.

As shown in FIGS. 5A, 5A-1, and 5A-2, the dielectric layer 560 is formed over the isolation layer 520 and the source/drain structures 550, in accordance with some embodiments. The dielectric layer 560 includes an oxide-containing material such as silicon oxide, in accordance with some embodiments.

The dielectric layer 560 is formed by a deposition process and a planarization process, in accordance with some embodiments. The deposition process includes a chemical vapor deposition (CVD) process, in accordance with some embodiments. The planarization process includes a chemical mechanical polishing (CMP) process, in accordance with some embodiments.

The gate stack 530 and the source/drain structures 550 together form a transistor 20, in accordance with some embodiments. The transistor 20 includes a gate all around (GAA) transistor, in accordance with some embodiments.

As shown in FIG. 5B, the step of FIG. 1B is performed to form the contact structures 180 in the dielectric layer 560, in accordance with some embodiments. The contact structures 180 pass through the dielectric layer 560, in accordance with some embodiments. The contact structures 180 are connected to the source/drain structures 550 respectively, in accordance with some embodiments.

As shown in FIG. 5C, the steps of FIGS. 1C-1E are performed to form the etch stop layer 190, the low-k dielectric layer 210, the dielectric layer 220, the conductive via structures 230, the dielectric layer 240, and the wiring layer 250, in accordance with some embodiments. In this step, a semiconductor device structure 500 is substantially formed, in accordance with some embodiments.

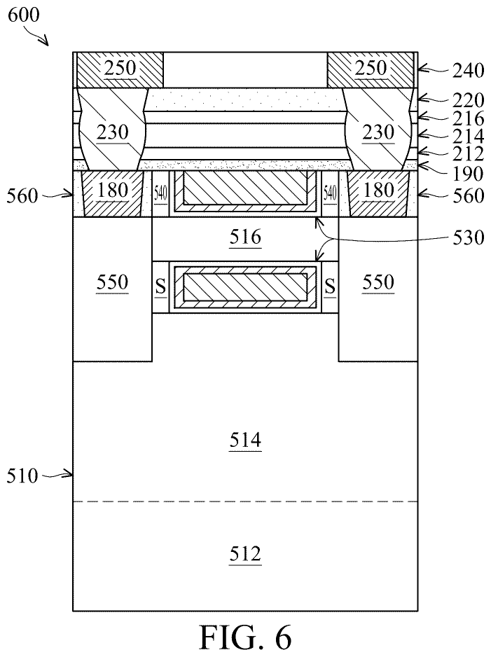

FIG. 6 is a cross-sectional view of a semiconductor device structure, in accordance with some embodiments. As shown in FIG. 6, after the step of FIG. 5B, the steps of FIGS. 2A-2C are performed to form the etch stop layer 190, the low-k dielectric layers 212, 214, and 216, the dielectric layer 220, the conductive via structures 230, the dielectric layer 240, and the wiring layer 250, in accordance with some embodiments. In this step, a semiconductor device structure 600 is substantially formed, in accordance with some embodiments.

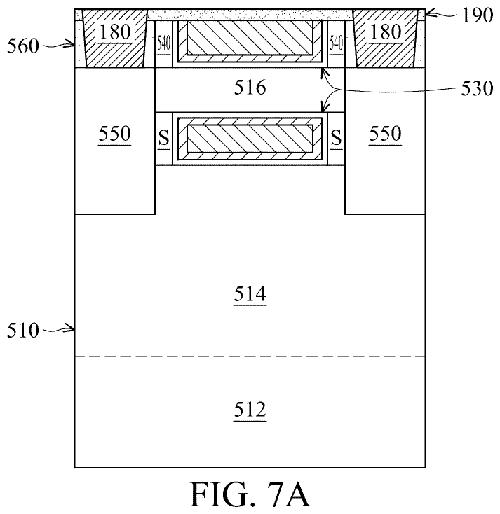

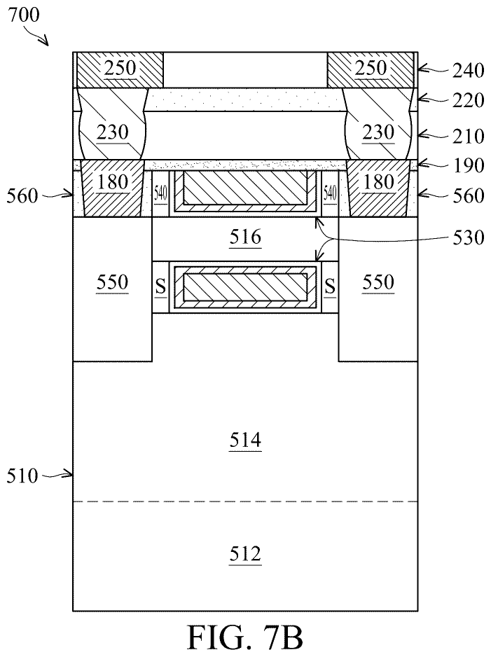

FIGS. 7A-7B are cross-sectional views of various stages of a process for forming a semiconductor device structure, in accordance with some embodiments. As shown in FIG. 7A, after the step of FIG. 5A, the step of FIG. 3A is performed to form the etch stop layer 190 and the contact structures 180, in accordance with some embodiments.

The etch stop layer 190 is formed over the gate stack 130, the spacer layer 150, and the dielectric layer 170, in accordance with some embodiments. The contact structures 180 pass through the dielectric layer 560 and the etch stop layer 190, in accordance with some embodiments. The contact structures 180 are connected to the source/drain structures 550 respectively, in accordance with some embodiments.

As shown in FIG. 7B, the steps of FIGS. 3B-3D are performed to form the low-k dielectric layer 210, the dielectric layer 220, the conductive via structures 230, the dielectric layer 240, and the wiring layer 250, in accordance with some embodiments. In this step, a semiconductor device structure 700 is substantially formed, in accordance with some embodiments.

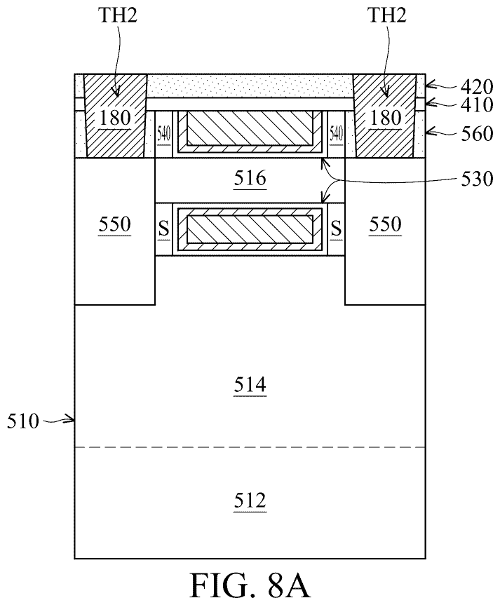

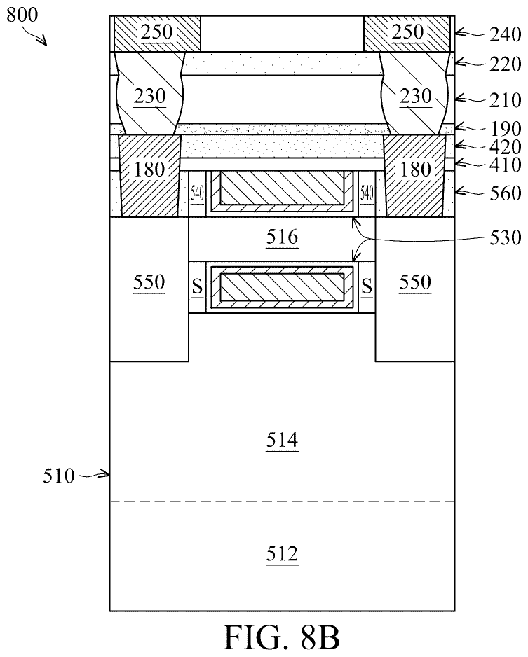

FIGS. 8A-8B are cross-sectional views of various stages of a process for forming a semiconductor device structure, in accordance with some embodiments.

As shown in FIG. 8A, after the step of FIG. 5A, the step of FIG. 4A is performed to form the etch stop layer 410, the dielectric layer 420, and the contact structures 180, in accordance with some embodiments. The contact structures 180 pass through the etch stop layer 410, the dielectric layer 420, and the dielectric layer 560, in accordance with some embodiments. The contact structures 180 are connected to the source/drain structures 550 respectively, in accordance with some embodiments.

Thereafter, as shown in FIG. 8B, the steps of FIGS. 4B-4D are performed to form the etch stop layer 190, the low-k dielectric layer 210, the dielectric layer 220, the conductive via structures 230, the dielectric layer 240, and the wiring layer 250, in accordance with some embodiments. In this step, a semiconductor device structure 800 is substantially formed, in accordance with some embodiments.

The application can be used over transistors, such as FinFET, GAA transistors, complementary field-effect transistors (CFET), or other suitable transistors, in accordance with some embodiments.

Processes and materials for forming the semiconductor device structures 500, 600, 700 and 800 may be similar to, or the same as, those for forming the semiconductor device structures 100, 200, 300, and 400 described above. Elements designated by the same or similar reference numbers as those in FIGS. 1A to 8B have the same or similar structures and the materials. Therefore, the detailed descriptions thereof will not be repeated herein.

In accordance with some embodiments, semiconductor device structures and methods for forming the same are provided. The methods (for forming the semiconductor device structure) form a low-k dielectric layer between an etch stop layer and a dielectric layer over a gate stack and contact structures to reduce the dielectric constant of a dielectric structure, which includes the etch stop layer, the low-k dielectric layer, and the dielectric layer. Therefore, the capacitor between a wiring layer, which is over the dielectric layer, and the gate stack and between the wiring layer and contact structures is reduced, which reduces RC time delay between the wiring layer and the gate stack and between the wiring layer and contact structures. As a result, the performance of the semiconductor device structure is improved.

In accordance with some embodiments, a method for forming a semiconductor device structure is provided. The method includes providing a substrate, a first source/drain structure, a second source/drain structure, a gate stack, a first dielectric layer, and a contact structure over the substrate. The gate stack is between the first source/drain structure and the second source/drain structure, the first dielectric layer surrounds the gate stack, and the contact structure passes through the first dielectric layer and is connected to the first source/drain structure. The method includes forming an etch stop layer over the gate stack, the first dielectric layer, and the contact structure. The method includes forming a first low-k dielectric layer over the etch stop layer. The method includes forming a second dielectric layer over the first low-k dielectric layer, wherein a first dielectric constant of the first low-k dielectric layer is lower than a second dielectric constant of the second dielectric layer. The method includes forming a conductive via structure passing through the second dielectric layer, the first low-k dielectric layer, and the etch stop layer.

In accordance with some embodiments, a method for forming a semiconductor device structure is provided. The method includes providing a substrate, a first source/drain structure, a second source/drain structure, a gate stack, and a first dielectric layer over the substrate. The gate stack is between the first source/drain structure and the second source/drain structure, and the first dielectric layer surrounds the gate stack. The method includes forming a first etch stop layer over the gate stack and the first dielectric layer. The method includes forming a contact structure passing through the first dielectric layer and the first etch stop layer and connected to the first source/drain structure. The method includes forming a low-k dielectric layer over the first etch stop layer and the contact structure. The method includes forming a second dielectric layer over the low-k dielectric layer, wherein a first dielectric constant of the low-k dielectric layer is lower than a second dielectric constant of the second dielectric layer. The method includes forming a conductive via structure passing through the second dielectric layer and the low-k dielectric layer.

In accordance with some embodiments, a semiconductor device structure is provided. The semiconductor device structure includes a substrate. The semiconductor device structure includes a first source/drain structure, a second source/drain structure, and a gate stack over the substrate. The gate stack is between the first source/drain structure and the second source/drain structure. The semiconductor device structure includes a first dielectric layer surrounding the gate stack. The semiconductor device structure includes a contact structure passing through the first dielectric layer and connected to the first source/drain structure. The semiconductor device structure includes a first etch stop layer over the gate stack and the first dielectric layer. The semiconductor device structure includes a first low-k dielectric layer over the first etch stop layer. The semiconductor device structure includes a second dielectric layer over the first low-k dielectric layer, wherein a first dielectric constant of the first low-k dielectric layer is lower than a second dielectric constant of the second dielectric layer. The semiconductor device structure includes a conductive via structure passing through the second dielectric layer and the first low-k dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
providing a substrate, a first source/drain structure, a second source/drain structure, a gate stack, a first dielectric layer, and a contact structure over the substrate, wherein the gate stack is between the first source/drain structure and the second source/drain structure, the first dielectric layer surrounds the gate stack, and the contact structure passes through the first dielectric layer and is connected to the first source/drain structure;
forming an etch stop layer over the gate stack, the first dielectric layer, and the contact structure;
forming a first low-k dielectric layer over the etch stop layer;
forming a second dielectric layer over the first low-k dielectric layer, wherein a first dielectric constant of the first low-k dielectric layer is lower than a second dielectric constant of the second dielectric layer; and
forming a conductive via structure passing through the second dielectric layer, the first low-k dielectric layer, and the etch stop layer.

2. The method for forming the semiconductor device structure as claimed in claim 1, wherein the first dielectric constant of the first low-k dielectric layer is lower than a third dielectric constant of the etch stop layer.

3. The method for forming the semiconductor device structure as claimed in claim 1, wherein the second dielectric layer is thicker than the etch stop layer.

4. The method for forming the semiconductor device structure as claimed in claim 1, wherein the conductive via structure has a first end portion, a second end portion, and a middle portion connected between the first end portion and the second end portion, the first end portion passes through the second dielectric layer, the second end portion passes through the etch stop layer, the middle portion passes through the first low-k dielectric layer, and the middle portion has a convex curved sidewall in a cross-sectional view.

5. The method for forming the semiconductor device structure as claimed in claim 4, wherein the middle portion is wider than the first end portion.

6. The method for forming the semiconductor device structure as claimed in claim 5, wherein a width of an upper part of the middle portion decreases toward the first end portion.

7. The method for forming the semiconductor device structure as claimed in claim 1, further comprising:
forming a second low-k dielectric layer over the etch stop layer, wherein the first low-k dielectric layer is formed over the second low-k dielectric layer, the first dielectric constant of the first low-k dielectric layer is lower than a third dielectric constant of the second low-k dielectric layer, and the third dielectric constant of the second low-k dielectric layer is lower than a fourth dielectric constant of the etch stop layer.

8. The method for forming the semiconductor device structure as claimed in claim 7, wherein the conductive via structure further passes through the second low-k dielectric layer, the conductive via structure has a first portion and a second portion, the first portion and the second portion pass through the first low-k dielectric layer and the second low-k dielectric layer respectively, and the first portion is wider than the second portion.

9. The method for forming the semiconductor device structure as claimed in claim 7, further comprising:
forming a third low-k dielectric layer over the first low-k dielectric layer, wherein the second dielectric layer is formed over the third low-k dielectric layer, the first dielectric constant of the first low-k dielectric layer is lower than a fifth dielectric constant of the third low-k dielectric layer, and the fifth dielectric constant is lower than the second dielectric constant of the second dielectric layer.

10. The method for forming the semiconductor device structure as claimed in claim 9, wherein the conductive via structure further passes through the third low-k dielectric layer, the conductive via structure has a first portion and a second portion, the first portion and the second portion pass through the first low-k dielectric layer and the third low-k dielectric layer respectively, and the first portion is wider than the second portion.

11. A method for forming a semiconductor device structure, comprising:
providing a substrate, a first source/drain structure, a second source/drain structure, a gate stack, and a first dielectric layer over the substrate, wherein the gate stack is between the first source/drain structure and the second source/drain structure, and the first dielectric layer surrounds the gate stack;
forming a first etch stop layer over the gate stack and the first dielectric layer;
forming a contact structure passing through the first dielectric layer and the first etch stop layer and connected to the first source/drain structure;
forming a low-k dielectric layer over the first etch stop layer and the contact structure;
forming a second dielectric layer over the low-k dielectric layer, wherein a first dielectric constant of the low-k dielectric layer is lower than a second dielectric constant of the second dielectric layer; and
forming a conductive via structure passing through the second dielectric layer and the low-k dielectric layer.

12. The method for forming the semiconductor device structure as claimed in claim 11, further comprising:
forming a third dielectric layer over the second dielectric layer and the conductive via structure; and
forming a wiring layer in the third dielectric layer and connected to the conductive via structure.

13. The method for forming the semiconductor device structure as claimed in claim 11, wherein the conductive via structure has an upper portion, a lower portion, and a neck portion connected between the upper portion and the lower portion, the neck portion is narrower than the upper portion, and the neck portion is narrower than the lower portion.

14. The method for forming the semiconductor device structure as claimed in claim 11, further comprising:
forming a third dielectric layer over the first etch stop layer, wherein the contact structure further passes through the third dielectric layer.

15. The method for forming the semiconductor device structure as claimed in claim 14, further comprising:
forming a second etch stop layer over the third dielectric layer and the contact structure, wherein the second etch stop layer is between the third dielectric layer and the low-k dielectric layer, and the conductive via structure further passes through the second etch stop layer.

16. A semiconductor device structure, comprising:
a substrate;
a first source/drain structure, a second source/drain structure, and a gate stack over the substrate, wherein the gate stack is between the first source/drain structure and the second source/drain structure;
a first dielectric layer surrounding the gate stack;
a contact structure passing through the first dielectric layer and connected to the first source/drain structure;
a first etch stop layer over the gate stack and the first dielectric layer;
a first low-k dielectric layer over the first etch stop layer;
a second dielectric layer over the first low-k dielectric layer, wherein a first dielectric constant of the first low-k dielectric layer is lower than a second dielectric constant of the second dielectric layer; and
a conductive via structure passing through the second dielectric layer and the first low-k dielectric layer.

17. The semiconductor device structure as claimed in claim 16, wherein the conductive via structure further passes through the first etch stop layer.

18. The semiconductor device structure as claimed in claim 16, wherein the contact structure further passes through the first etch stop layer.

19. The semiconductor device structure as claimed in claim 18, further comprising:
a third dielectric layer between the first etch stop layer and the first low-k dielectric layer, wherein the contact structure further passes through the third dielectric layer; and
a second etch stop layer between the third dielectric layer and the first low-k dielectric layer, wherein the conductive via structure further passes through the second etch stop layer.

20. The semiconductor device structure as claimed in claim 16, further comprising:
a second low-k dielectric layer between the first low-k dielectric layer and the first etch stop layer, wherein the first dielectric constant of the first low-k dielectric layer is lower than a third dielectric constant of the second low-k dielectric layer, and the third dielectric constant is lower than a fourth dielectric constant of the first etch stop layer; and
a third low-k dielectric layer between the first low-k dielectric layer and the second dielectric layer, wherein the first dielectric constant of the first low-k dielectric layer is lower than a fifth dielectric constant of the third low-k dielectric layer, and the fifth dielectric constant is lower than the second dielectric constant of the second dielectric layer.
